(19) United States
(12) Patent Application Publication
(10) Pub. No.: US 2021/0280621 A1
(43) Pub. Date: Sep. 9, 2021

(54) OPTICAL DISC FOR FINGERPRINT RECOGNITION SENSOR AND OPTICAL FILTER COMPRISING SAME

(71) Applicant: LMS CO.,LTD., Pyeongtaek-si Gyeonggi-do (KR)

(72) Inventors: Jeong Og CHOI, Seoul (KR); Jin Hwan KIM, Asan-si Chungcheongnam-do (KR); Young Soo AN, Yongin-si Gyeonggi-do (KR); Seon Ho YANG, Seoul (KR); Tae Kwang PARK, Pyeongtaek-si Gyeonggi-do (KR); Woo Joo LAH, Yongin-si Gyeonggi-do (KR)

(21) Appl. No.: 17/257,419

(22) PCT Filed: Jul. 1, 2019
(86) PCT No.: PCT/KR2019/007936

§ 371 Date: Dec. 31, 2020

(30) Foreign Application Priority Data
Jul. 3, 2018 (KR) 10-2018-0076965
Jan. 11, 2019 (KR) 10-2019-0003914

(51) Int. Cl. H01L 27/146; G02B 5/20; G02B 5/22; G06K 9/00

(52) U.S. Cl. CPC H01L 27/14621; G06K 9/0004; G02B 5/22; G02B 5/207

(57) ABSTRACT

The present invention relates to an optical disc capable of positioning a fingerprint recognition region in a screen of a display, and an optical filter comprising same. The optical disc according to the present invention comprises a light absorption layer, which transmits light in a green region of visible light to increase a fingerprint recognition rate and effectively absorbs light in a red region so as to suppress a phenomenon in which the fingerprint recognition region in the screen of the display appears in red.

### TECHNICAL FIELD

The present invention relates to an optical disc, in which a region in which a fingerprint is recognized may be positioned in a screen of a display device, and an optical filter including the same.

### BACKGROUND ART

Various methods such as pattern input methods, which have been applied since early on, fingerprint recognition methods, and iris recognition methods have been introduced as security methods for releasing a locked state of smartphones. Among the methods, methods of inputting biometric information, such as fingerprint recognition methods or iris recognition methods, are preferred because it is difficult for other people to gain access, and the adoption thereof is increasing.

Among such biometrics, a capacitive fingerprint recognition occupied most of fingerprint recognition methods in the beginning. The capacitive fingerprint recognition method is a method in which a capacitor is charged in response to a pressure of a valley of a fingerprint so as to read the fingerprint, and there are advantages thereto such as high recognition rate and reliability.

However, along with the development of smartphones, a desire to widely use a smartphone screen is increasing. Thus, as an attempt to use a physical button positioned on a front surface as a touch panel is increasing, the capacitive fingerprint recognition method may no longer be available. In order to use the capacitive fingerprint recognition method, a fingerprint recognition sensor should be positioned separately from a display, which is not consistent with a current trend of widely using a smartphone screen.

Security methods reflecting such a demand are optical fingerprint recognition methods. Although these are limited to organic light-emitting diodes (OLEDs), in optical fingerprint recognition methods, an optical fingerprint recognition sensor can be positioned inside a display. In order to increase the recognition rate of such an optical fingerprint recognition sensor, there is a need for a visible light transmission filter that transmits only a wavelength of light used as signal light.

### DISCLOSURE

### Technical Problem

The present invention is directed to providing an optical disc, in which a region in which a fingerprint is recognized may be positioned in a screen of a display device, and an optical filter including the same.

### Technical Solution

According to one embodiment of the present invention, an optical disc for a fingerprint recognition sensor is provided.

The optical disc may include a light-transmitting substrate and a light absorption layer.

The light absorption layer may be formed on one surface or each of both surfaces of the light-transmitting substrate.

The light absorption layer may include a resin binder and a light absorber dispersed in the resin binder.

The light absorption layer may have an average optical transmittance of 15% or less in a wavelength range of 620 nm to 710 nm.

According to one embodiment of the present invention, an optical filter is provided.

The optical filter includes the above-described optical disc and a selective wavelength reflection layer.

The selective wavelength reflection layer may be formed on one surface or each of both surfaces of the optical disc.

According to one embodiment of the present invention, a fingerprint recognition module is provided.

The fingerprint recognition module includes the above-described optical filter.

### Advantageous Effects

An optical disc for a fingerprint recognition sensor according to the present invention transmits light in a green region of visible light to increase a fingerprint recognition rate and includes a light absorption layer that effectively absorbs light in a red region of the visible light, thereby suppressing a phenomenon in which a region of a display screen, in which a fingerprint is recognized, appears red.

### DESCRIPTION OF DRAWINGS

FIG. 1 is a cross-sectional view illustrating a stacked structure of an optical disc according to one embodiment of the present invention.

FIG. 2 is a cross-sectional view illustrating a stacked structure of an optical filter according to one embodiment of the present invention.

FIGS. 3 and 4 are cross-sectional views illustrating stacked structures of a fingerprint recognition module according to one embodiment of the present invention.

FIG. 5 shows results of comparing and observing the visibilities of optical filters according to wavelengths of irradiated light.

FIG. 6 is a graph of light absorption of optical discs according to wavelengths.

FIG. 7 is a graph of light transmissions of optical filters according to wavelengths.

### MODES OF THE INVENTION

Various modifications may be made to the present invention, and the present invention may be implemented in various embodiments, and specific embodiments thereof are shown by way of example in the accompanying drawings and will herein be described in detail.

However, it should be understood that there is no intention to limit the present invention to the specific embodiments, and on the contrary, the present invention is to cover all modifications, equivalents, and alternatives falling within the spirit and scope of the present invention.

It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Also, in the present specification, it should be understood that the accompanying drawings are to be enlarged or reduced for convenience of description.

Hereinafter, the present invention will be described in detail with reference to the accompanying drawings. Throughout the specification, like reference numerals designate like elements and a repetitive description thereof will be omitted.

The present invention relates to an optical disc for a fingerprint recognition sensor.

Various methods such as pattern input methods, which have been applied since early on, fingerprint recognition methods, and iris recognition methods have been introduced as security methods for releasing a locked state of smartphones. Among the methods, methods of inputting biometric information, such as fingerprint recognition methods or iris recognition methods, are preferred because it is difficult for other people to gain access, and the adoption thereof is increasing.

Among such biometrics, a capacitive fingerprint recognition occupied most of fingerprint recognition methods in the beginning. The capacitive fingerprint recognition method is a method in which a capacitor is charged in response to a pressure of a valley of a fingerprint so as to read the fingerprint, and there are advantages thereto such as high recognition rate and reliability.

However, along with the development of smartphones, a desire to widely use a smartphone screen is increasing. Thus, as an attempt to use a physical button positioned on a front surface as a touch panel is increasing, the capacitive fingerprint recognition method may no longer be available. In order to use the capacitive fingerprint recognition method, a fingerprint recognition sensor should be positioned separately from a display, which is not consistent with a current trend of widely using a smartphone screen.

Security methods reflecting such a demand are optical fingerprint recognition methods. In the optical fingerprint recognition methods, an optical fingerprint recognition sensor can be positioned inside a display. In order to increase the recognition rate of such an optical fingerprint recognition sensor, there is a need for a visible light transmission filter that transmits only a wavelength of light used as signal light.

Accordingly, the present invention provides an optical disc for a fingerprint recognition sensor.

The optical disc for a fingerprint recognition sensor according to the present invention transmits light in a green region of visible light to increase a fingerprint recognition rate and includes a light absorption layer that effectively absorbs light in a red region of the visible light, thereby suppressing a phenomenon in which a region of a display screen, in which a fingerprint is recognized, appears red.

Hereinafter, the present invention will be described in detail.

Optical Disc

One embodiment of the present invention provides an optical disc.

The optical disc includes a light-transmitting substrate and a light absorption layer formed on one surface or each of both surfaces of the substrate.

The light absorption layer includes a resin binder and a light absorber dispersed in the resin binder.

The optical disc for a fingerprint recognition sensor has an average transmittance of 15% or less with respect to light in a wavelength range of 620 nm to 710 nm.

The optical disc for a fingerprint recognition sensor according to the present invention includes the light-transmitting substrate and the light absorption layer including the light absorber. The light absorption layer has an absorption peak in a visible light region (550 nm to 750 nm), and the optical disc has a cut-off of 580 nm to 620 nm and serves to absorb light of a wavelength of 620 nm to 700 nm, at which a red color is exhibited.

In one embodiment, the optical disc for a fingerprint recognition sensor according to the present invention may absorb a certain scale of light in a red region of visible light to reduce a phenomenon in which a display appears red.

Specifically, when a transmittance of the optical disc is measured in a wavelength range of 300 nm to 1,200 nm using a spectrophotometer, with respect to light of a wavelength of 620 nm to 710 nm, average transmittance may be 15% or less, 13% or less, 10% or less, or 7% or less, and an average lower limit thereof may be, for example, 1% or more or 3% or more. More specifically, the optical disc may have an average transmittance of 1% to 10% or 3% to 5% with respect to the light of a wavelength of 620 nm to 710 nm.

In addition, the optical disc for a fingerprint recognition sensor according to the present invention may satisfy Condition 1 below.

10 nm<|T_{10%}−T_{50%}|<50 nm [Condition 1]

T_{50%} refers to a wavelength value at a point at which optical transmittance is 50% at a wavelength of 550 nm to 710 nm.

T_{10%} refers to a wavelength value at a point at which optical transmittance is 10% at a wavelength of 550 nm to 710 nm.

Specifically, in the optical disc, an absolute value of a difference between the wavelength value (T_{50%)} at a point at which optical transmittance is 50% at a wavelength of 550 nm to 710 nm and the wavelength value (T_{10%}) at a point at which optical transmittance is 10% at a wavelength of 550 nm to 710 nm may be 50 nm or less, 40 nm or less, 30 nm or less, or 25 nm or less, and a lower limit thereof may be 10 nm or more or 15 nm or more.

Furthermore, in the optical disc for a fingerprint recognition sensor according to the present invention, when a transmittance of the optical disc is measured in a wavelength range of 300 nm to 1,200 nm using a spectrophotometer, optical transmittance may be 85% or more at a wavelength of 430 nm to 560 nm. Specifically, at a wavelength of 430 nm to 560 nm, the optical disc may have an optical transmittance of 85% or more, 88% or more, 90% or more, or 92% or more, and an upper limit of the optical transmittance may be 95% or less, 98% or less, 99% or less, or 100%. More specifically, the optical disc may have an optical transmittance of 90% to 99% or 92% to 95% at a wavelength of 430 nm to 560 nm.

Hereinafter, each component of the optical disc according to the present invention will be described in more detail.

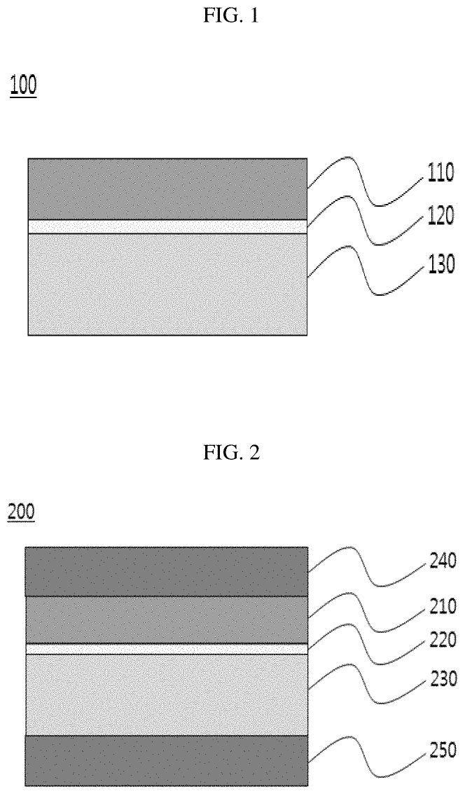

As shown in FIG. 1, an optical disc 100 for a fingerprint recognition sensor according to the present invention may have a structure in which a primer layer 120 and a light absorption layer 110 are sequentially stacked on a light-transmitting substrate 130. The primer layer 120 may be omitted. In addition, the light absorption layer 110 has a structure in which a light-absorbing dye absorbing light in a red region of visible light is dispersed in a resin and is also referred to as a red absorption layer. The light-transmitting substrate 130 may be replaced with a resin substrate or the like.

First, the optical disc for a fingerprint recognition sensor according to the present invention may include the light-transmitting substrate. A light-transmitting substrate is not particularly limited as long as the light-transmitting substrate is transparent and is a plate-shaped substrate, but specifically, a transparent glass substrate, a transparent resin substrate, or the like may be used as the light-transmitting substrate.

Specifically, when a transparent glass substrate is used as the light-transmitting substrate, a commercially available transparent glass substrate may be used, and if necessary, a phosphate-based glass substrate including copper oxide (CuO) may be used. In addition, a transparent resin substrate may be used without particular limitation as long as the transparent resin substrate has excellent strength. For example, a light-transmitting resin in which an inorganic filler is dispersed may be used, and a binder resin usable in the light absorption layer may be used.

The transparent glass substrate can prevent thermal deformation and warpage according to a manufacturing process of an optical filter without lowering optical transmittance of visible light. In the transparent resin substrate, when the binder resin of the light absorption layer is used for the transparent resin substrate, a type of the binder resin of the light absorption layer and a type of the resin used for the light-transmitting substrate may be controlled in the same or a similar manner, thereby improving a degree of interfacial peeling.

In addition, the optical disc according to the present invention includes the light absorption layer. The light absorption layer may be formed on one surface or each of both surfaces of the substrate and may include a resin binder and a light absorber dispersed in the resin binder.

In the light absorption layer, when a transmittance of the optical disc is measured in a wavelength range of 300 nm to 1,200 nm using a spectrophotometer, the shortest wavelength (λ_cut-off), at which the transmittance is 50% at a wavelength longer than a wavelength of 550 nm, is present within a wavelength of 580 nm to 620 nm. Specifically, the shortest wavelength (λ_cut-off), at which the transmittance is 50% at a wavelength longer than a wavelength of 550 nm of the optical disc, is present within a wavelength of 590 nm to 610 nm.

The light absorber according to the present invention is a compound having a near-infrared absorption peak in a wavelength range of 650 nm to 700 nm and serves to absorb light in a near-infrared region incident on an optical filter to block the light in a near-infrared region from being incident on an image sensor.

In this case, as the light absorber, a compound is not particularly limited as long as the compound has a near-infrared absorption peak (λₘₐₓ) in a wavelength range of 640 nm to 700 nm. However, specifically, the light absorber may include at least one of a dye having an absorption peak of 630±15 nm, a dye having an absorption peak of 650±15 nm, and a dye having an absorption peak of 680±15 nm. For example, the dyes may include SDA6698 (with an absorption peak of 651 nm manufactured by H.W. Sands Corp.), SDA4451 (with an absorption peak of 634 nm manufactured by H.W. Sands Corp.), and VIS680D (an absorption peak of 680 nm manufactured by QCR Solutions Corp.).

In addition, the light absorber may be used alone, and in some cases, three or more types of light absorbers may be used in combination, or the light absorber may be used by being separated into two layers. In addition, a content of the light absorber may be selected without being limited within a range that does not affect an optical absorbance of the optical disc. Specifically, the light absorber may have a content of 0.01 to 10.0 parts by weight, 0.01 to 8.0 parts by weight, or 0.01 to 5.0 parts by weight with respect to 100 parts by weight of the binder resin included in the light absorption layer.

Next, the light absorption layer according to the present invention may include the binder resin.

Examples of the binder resin according to the present invention may include a cyclic olefin-based resin, a polyarylate-based resin, a polysulfone resin, a polyethersulfone resin, a polyparaphenylene resin, a polyarylene ether phosphine oxide resin, a polyimide resin, a polyetherimide resin, a polyamideimide resin, an acrylic resin, a polycarbonate resin, a polyethylene naphthalate resin, an organic-inorganic hybrid-based resin, and the like. Specifically, a cyclic olefin polymer (COP), a cyclic olefin copolymer (COC), a polyimide (PI), or a mixture thereof may be used.

Furthermore, the binder resin may further include an additive.

As the additive, any material may be used without particular limitation as long as the material can prevent the denaturalization of the light absorption layer at a high temperature. For example, there may be a phenol-based antioxidant, a tin-based stabilizer, or the like etc, but the present invention is not limited thereto.

Optical Filter

In addition, one embodiment of the present invention provides an optical filter.

The optical filter includes the above-described optical disc and a selective wavelength reflection layer.

The selective wavelength reflection layer may be formed on one surface or each of both surfaces of the optical disc.

The optical filter according to the present invention may include the selective wavelength reflection layer formed on one surface or each of both surfaces of the optical disc. Specifically, the optical filter may include the selective wavelength reflection layers formed on both surfaces of the optical disc, and when a transmittance of the optical filter is measured in a wavelength range of 300 nm to 1,200 nm using a spectrophotometer, the shortest wavelength (λ_cut-off), in which the transmittance is 50% at a wavelength longer than a wavelength of 550 nm, may be present within a wavelength of 585 nm to 615 nm. In addition, when a transmittance of the optical filter is measured in a wavelength range of 300 nm to 1,200 nm using a spectrophotometer, the longest wavelength (λ_cut-off), in which the transmittance is 50% at a wavelength longer than a wavelength of 550 nm, may be present within a wavelength of 615 nm to 655 nm.

In addition, in the optical filter according to the present invention, when a transmittance of the optical disc is measured in a wavelength range of 300 nm to 1,200 nm using a spectrophotometer, optical transmittance at a wavelength of 650 nm to 1,200 nm may be 5% or less, 4% or less, or 3% or less, and an average lower limit thereof may be, for example, 0.5% or more or 1% or more.

Furthermore, in the optical filter according to the present invention, when a transmittance of the optical disc is measured in a wavelength range of 300 nm to 1,200 nm using a spectrophotometer, an optical transmittance at a wavelength of 430 nm to 560 nm may be 90% or more, 93% or more, 95% or more, or 97% or more, and an average upper limit thereof may be 99% or less or 100%.

In addition, the optical filter according to the present invention may satisfy Condition 1 below.

|T_{10%}−T_{50%}|<50 nm [Condition 1]

T_{50%} refers to a wavelength value at a point at which optical transmittance is 50% at a wavelength of 550 nm to 710 nm.

T_{10%} refers to a wavelength value at a point at which optical transmittance is 10% at a wavelength of 550 nm to 710 nm.

Specifically, in the optical filter, an average absolute value of a difference between the wavelength value (T_{50%}) at a point at which optical transmittance is 50% at a wavelength of 550 nm to 710 nm and the wavelength value (T_{10%}) at a point at which optical transmittance is 10% at a wavelength of 550 nm to 710 nm may be 50 nm or less, 40 nm or less, 30 nm or less, or 25 nm or less, and an average lower limit thereof may be 50 nm or more or 10 nm or more.

Hereinafter, each component constituting the optical filter according to the present invention will be described in more detail.

As shown in FIG. 2, an optical filter 200 according to the present invention has a structure in which an optical disc is formed to have a structure in which a primer layer 220 and an absorption layer 230 are sequentially stacked on a light-transmitting substrate 230, and first and second selective wavelength reflection layers 240 and 250 are respectively formed on and below the optical disc. The first and second selective wavelength reflection layers 240 and 250 may each have a structure in which TiO₂ and SiO₂ are alternately stacked.

First, the optical filter according to the present invention may include the selective wavelength reflection layer on one surface or each of both surfaces of the optical disc.

Specifically, the selective wavelength reflection layer may serve to reflect light in a near-infrared region and may have a structure of a dielectric multi-layered film or the like in which a high refractive index layer and a low refractive index layer are alternately stacked, but the present invention is not limited thereto. In addition, the selective wavelength reflection layer serves to reflect light of a wavelength of 700 nm or more, specifically, light of a wavelength of 700 nm to 1,100 nm, among light beams incident to the optical filter and to block the light of the wavelength from being incident on an image sensor. Alternatively, the selective wavelength reflection layer serves to prevent reflection of visible light in a wavelength range of 400 nm to 700 nm. That is, the selective wavelength reflection layer may serve as an infrared reflective layer (IR layer) that reflects near infrared rays and/or an anti-reflection layer (AR layer) that prevents visible light from being reflected.

In this case, the selective wavelength reflection layer may have a structure of a dielectric multi-layered film or the like in which a high refractive index layer and a low refractive index layer are alternately stacked and may further include an aluminum deposition film, a precious metal thin film, or a resin film in which one or more fine particles of indium oxide and tin oxide are dispersed. For example, the selective wavelength reflection layer may have a structure in which a dielectric multi-layered film having a first refractive index and a dielectric multi-layered film having a second refractive index are alternately stacked, and the dielectric multi-layered film having the first refractive index and the dielectric multi-layered film having the second refractive index may have a refractive index deviation of 0.2 or more, 0.3 or more, or 0.2 to 1.0.

In addition, the high refractive index layer and the low refractive index layer of the selective wavelength reflection layer are not particularly limited as long as a refractive index deviation between the high refractive index layer and the low refractive index layer are included in the above-described range. However, the high refractive index layer may include at least one selected from the group consisting of titanium oxide, aluminum oxide, zirconium oxide, tantalum pentoxide, niobium pentoxide, lanthanum oxide, yttrium oxide, zinc oxide, zinc sulfide, and indium oxide which have a refractive index of 2.1 to 2.5. The indium oxide may further include a small amount of titanium oxide, tin oxide, cerium oxide, or the like. In addition, the low refractive index layer may include at least one selected from the group consisting of silicon dioxide, lanthanum fluoride, magnesium fluoride, and sodium aluminum hexafluoride (cryolite (Na₃AlF₆)) which have a refractive index of 1.4 to 1.6.

Fingerprint Recognition Module

Furthermore, one embodiment of the present invention provides a fingerprint recognition module.

The fingerprint recognition module includes the above-described optical filter.

The fingerprint recognition module according to the present invention may include the above-described optical filter and a fingerprint recognition sensor on one surface of the optical filter. In this case, the fingerprint recognition sensor may be a camera type or an optical type. Specifically, the fingerprint recognition module of the present invention may include the above-described optical filter (filter for a fingerprint recognition sensor), the fingerprint recognition sensor, and a circuit board for a fingerprint recognition sensor. More specifically, the fingerprint recognition module may have a structure in which the optical filter, the fingerprint recognition sensor, and the circuit board for a fingerprint recognition sensor are sequentially stacked.

Specifically, the optical filter may include an optical disc for a fingerprint recognition sensor that includes a light-transmitting substrate and a light absorption layer that is formed on one surface or each of both surfaces of the substrate and includes a resin binder and a light absorber dispersed in the resin binder.

The optical disc for a fingerprint recognition sensor has an average optical transmittance of 15% or less at a wavelength of 620 nm to 710 nm.

More specifically, the optical filter may include the above-described optical disc and a selective wavelength reflection layer formed on one surface or each of both surfaces of the optical disc.

As an example, in the fingerprint recognition module of the present invention, the optical filter may be a filter for a fingerprint recognition sensor, and the fingerprint recognition sensor including the optical filter may be positioned in a screen region of a display (in-display).

Since the fingerprint recognition module according to the present invention includes the above-described optical filter, the visibility of red light is reduced, thereby preventing a display screen from appearing red.

Display Device

In addition, one embodiment of the present invention provides a display device.

The display device includes the above-described fingerprint recognition module.

The display device according to the present invention may include the fingerprint recognition module in a screen region of a display (in-display). In the present invention, the fingerprint recognition module being positioned in the screen region of the display (in-display) means that the fingerprint recognition module is present in an emission region of a display panel and is positioned opposite to an emission surface of the display panel.

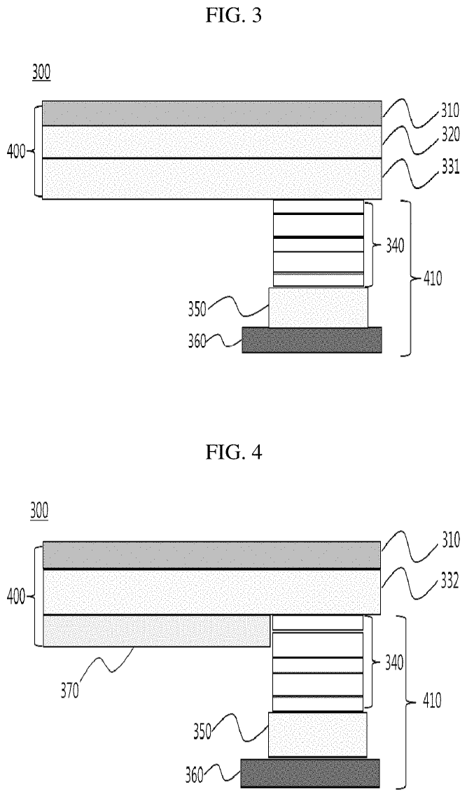

As an example, as shown in FIG. 3, the present invention may provide an organic light-emitting diode (OLED) display device. Specifically, an OLED display device 300 may include a fingerprint recognition module 410 in a region of an OLED display screen 400. More specifically, the OLED display device 300 may include the OLED display screen 400 and the above-described fingerprint recognition module 410 below the OLED display screen 400. For example, the OLED display screen 400 may have a structure in which a screen protection layer 310, a cover glass 320, and an OLED display panel 331 are sequentially stacked and may have a structure in which the fingerprint recognition module 410 is positioned below the OLED display screen 400. The fingerprint recognition module 410 has a structure in which an optical filter 340, a fingerprint recognition sensor 350, and a circuit board 360 for a fingerprint recognition sensor are sequentially stacked. The optical filter 340 may be a filter for a fingerprint recognition sensor.

In addition, as shown in FIG. 4, the present invention may provide a liquid crystal display (LCD) device. Specifically, the LCD device 300 may include a fingerprint recognition module 410 in a region of an LCD screen 400. More specifically, the LCD device 300 may include the LCD display screen 400 and a fingerprint recognition module 410 below the LCD screen 400. For example, the LCD screen 400 may have a structure in which a screen protection layer 310, an LCD panel 332, and a backlight unit 370 are sequentially stacked and may include the fingerprint recognition module 410 below the LCD screen 400. The fingerprint recognition module 410 may be positioned at a portion to which the backlight unit 370 is not applied.

In addition, the fingerprint recognition module 410 may be positioned below the backlight unit 370. That is, the position of the fingerprint recognition module 410 is not limited according to the position to which the backlight unit 370 is applied or the position to which the backlight unit 370 is not applied, and the fingerprint recognition module 410 may be positioned differently according to a fingerprint recognition rate.

The fingerprint recognition module 410 has a structure including an optical filter 340, a fingerprint recognition sensor 350, and a circuit board 360 for a fingerprint recognition sensor.

Hereinafter, the present invention will be described in more detail through Examples and Experimental Examples.

However, the following Examples and Experimental Examples are for illustrative purposes only and not intended to limit the scope of the present invention.

### Example 1

Light absorber A, light absorber B, and light absorber C respectively having absorption peaks at wavelengths of 645±5 nm, 670±5 nm, and 685±5 nm were commercially obtained and each mixed at a content of 0.5 to 5 parts by weight based on 100 parts by weight of a resin. In this case, a polymethyl methacrylate (PMMA) resin was used as the resin, and methyl ethyl ketone (MEK) was used as an organic solvent. Thereafter, all of the above materials were added and stirred using a magnetic stirrer for 24 hours or more to prepare a light-absorbing solution. The prepared light-absorbing solution was applied on both surfaces of a glass substrate having a thickness of 0.2 mm and cured at a temperature of 120° C. for 50 minutes to manufacture an optical disc including a light absorption layer.

When an optical transmittance of the optical disc was measured using a spectrophotometer, it was confirmed that a wavelength, at which the optical transmittance was a cut-off T_{50%}, was 590 nm.

### Example 2

SiO₂ and Ti₃O₅ were alternately deposited on a first main surface of the optical disc manufactured in Example 1 at a temperature of 110±5° C. using an E-beam evaporator, thereby forming a first selective wavelength reflection layer having a dielectric multi-layered structure. Thereafter, SiO₂ and Ti₃O₅ were alternately deposited on a second main surface of the optical disc at a temperature of 110±5° C. using an E-beam evaporator to form a second selective wavelength reflection layer having a dielectric multi-layered structure, thereby manufacturing an optical filter. In this case, the numbers and thicknesses of the stacked first and second selective wavelength reflection layers are shown in Table 2 below. Here, the thickness refers to the total thickness of each of the first and second selective wavelength reflection layers, and a unit thereof is micrometers (μm).

TABLE 1

| | First selective | | Second selective | |
|---|---|---|---|---|
| | wavelength | | wavelength | |
| | reflection layer | | reflection layer | |
| | Number | | Number | |
| | of layers | Thickness | of layers | Thickness |
| | [P1] | [D1] | [P2] | [D2] |
| Example 2 | 20 to 25 | 2 to 3 | 20 to 25 | 2 to 3 |

### Comparative Example 1

Light absorber B and light absorber C respectively having absorption peaks at wavelengths of 670±5 nm and 685±5 nm were commercially obtained and each mixed at a content of 0.5 to 5 parts by weight based on 100 parts by weight of a resin. In this case, a PMMA resin was used as the resin, and MEK was used as an organic solvent. Thereafter, all of the above materials were added and stirred using a magnetic stirrer for 24 hours or more to prepare a light-absorbing solution. The prepared light-absorbing solution was applied on both surfaces of a glass substrate having a thickness of 0.2 mm and dried at a high temperature of 120° C. for 50 minutes to manufacture an optical disc including a light absorption layer.

When an optical transmittance of the optical disc was measured using a spectrophotometer, it was confirmed that a wavelength, at which the optical transmittance was a cut-off T_{50%}, was 630 nm.

### Comparative Example 2

Light absorber C having an absorption peak at a wavelength of 685±5 nm was commercially obtained and mixed at a content of 0.5 to 5 parts by weight based on 100 parts by weight of a resin. In this case, a PMMA resin was used as the resin, and MEK was used as an organic solvent. Thereafter, all of the above materials were added and stirred using a magnetic stirrer for 24 hours or more to prepare a light-absorbing solution. The prepared light-absorbing solution was applied on both surfaces of a glass substrate having a thickness of 0.2 mm and dried at a high temperature of 120° C. for 50 minutes to manufacture an optical disc including a light absorption layer.

When an optical transmittance of the optical disc was measured using a spectrophotometer, it was confirmed that a wavelength, at which the optical transmittance was a cut-off T_{50%}, was 650 nm.

### Comparative Example 3

An optical filter was manufactured by depositing a dielectric multi-layered film in the same manner as in Example 2, except that the optical disc manufactured in Comparative Example 1 was used as an optical disc.

### Comparative Example 4

An optical filter was manufactured by depositing a dielectric multi-layered film in the same manner as in Example 2, except that the optical disc manufactured in Comparative Example 2 was used as an optical disc.

### Experimental Example 1

In order to confirm the optical characteristics of the optical discs and the optical filters including the optical discs according to the present invention, the following experiments were performed.

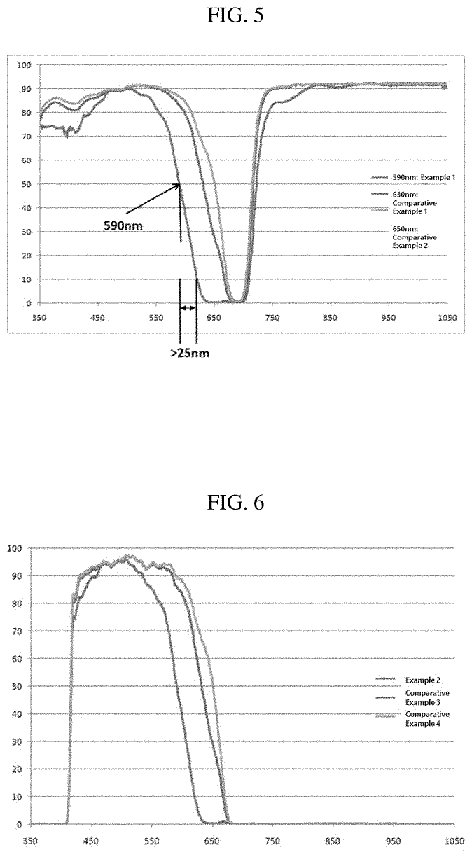

First, transmission spectra were measured on the optical discs manufactured in Example 1, Comparative Example 1, and Comparative Example 2 in a wavelength range of 350 nm to 1,200 nm under a condition of an incident angle of 0° using a spectrophotometer. Measurement results are shown in FIG. 5.

In addition, optical transmission spectra were measured on the optical filters manufactured in Example 2, Comparative Example 3, and Comparative Example 4. Measurement results are shown in FIG. 6.

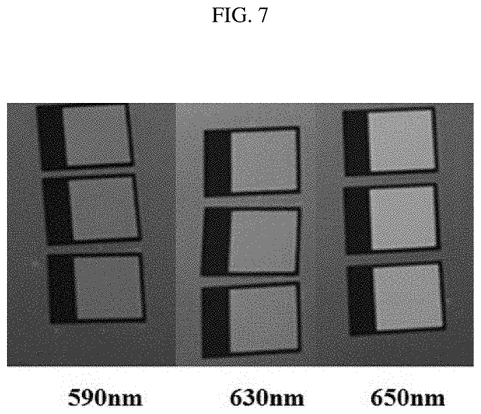

In addition, the visibility of a red color reflected from a filter was observed on the optical filters of Example 2, Comparative Example 3, and Comparative Example 4 in which cut-off T_{50%} values of the optical discs thereof were 590 nm, 630 nm, and 650 nm, respectively. Observation results are shown in FIG. 7.

Referring to FIG. 5, in the optical disc manufactured in Example 1, a point at which optical absorbance is 50% is present within a wavelength of 580 nm to 610 nm, and it can be seen that a difference in wavelength between a point at which optical absorbance is 50% and a point at which optical absorbance is 10% is within 25 nm. Specifically, when optical transmittance is measured, it can be confirmed that a wavelength, at which the optical transmittance is a cut-off T_{50%}, is 590 nm. On the other hand, in the optical discs manufactured in Comparative Example 1 and Comparative Example 2, when optical transmittance is measured, it can be confirmed that wavelengths, at which the optical transmittance is a cut-off T_{50%}, are in the range of 630 nm and 650 nm. Thus, in the optical disc according to the present invention, a wavelength of absorbed light can be adjusted by controlling a light absorber included in a light absorption layer, thereby absorbing light of a near-infrared wavelength.

In addition, referring to FIG. 6, it can be seen that the optical filter manufactured in Example 2 exhibits an optical transmittance of 80% or more at a wavelength of 400 nm to 580 nm and absorbs light of a wavelength of 580 nm or more. On the other hand, it can be seen that the optical filter manufactured in Comparative Example 3 exhibits an optical transmittance of 80% or more at a wavelength of 400 nm to 630 nm and absorbs light of a wavelength of 630 nm or more. In addition, it can be seen that the optical filter manufactured in Comparative Example 4 exhibits an optical transmittance of 80% or more at a wavelength of 400 nm to 650 nm and absorbs light of a wavelength of 650 nm or more. Therefore, it can be seen that the optical filters according to the present invention effectively absorb light in a red color region as compared with other optical filters.

Referring to FIG. 7, in the optical filter of Example 2 in which a cut-off T_{50%} value of the optical disc is applied at 590 nm, it can be experimentally confirmed that the visibility of a red color reflected from the optical filter is significantly reduced as compared with the optical filter of Comparative Example 3 in which a cut-off T_{50%} value of the optical disc is applied at 630 nm and the optical filter of Comparative Example 5 in which a cut-off T_{50%} value of the optical disc is applied at 650 nm. As a result, in the optical disc of the present invention, it can be seen that since a light absorber for absorbing light in a red color region is included in a light absorption layer, the visibility of a red color is reduced in an optical filter including the optical disc.

1. An optical disc for a fingerprint recognition sensor, comprising:
a light-transmitting substrate; and
a light absorption layer which is formed on one surface or each of both surfaces of the light-transmitting substrate, includes a resin binder and a light absorber dispersed in the resin binder, and has an average optical transmittance of 15% or less at a wavelength of 620 nm to 710 nm.

2. The optical disc of claim 1, wherein, when a transmittance of the optical disc is measured in a wavelength range of 300 nm to 1,200 nm using a spectrophotometer, a shortest wavelength (λ_cut-off), in which the transmittance is 50% at a wavelength longer than a wavelength of 550 nm, is present within a wavelength of 580 nm to 610 nm.

3. The optical disc of claim 1, wherein Condition 1 below is satisfied:
10 nm<|T_{10%}−T_{50%}|<50 nm, [Condition 1]
wherein T_{50%} refers to a wavelength value at a point at which optical transmittance is 50% at a wavelength of 550 nm to 710 nm, and
T_{10%} refers to a wavelength value at a point at which optical transmittance is 10% at a wavelength of 550 nm to 710 nm.

4. The optical disc of claim 1, wherein, when a transmittance of the optical disc is measured in a wavelength range of 300 nm to 1,200 nm using a spectrophotometer, optical transmittance is 10% or less at a wavelength of 640 nm to 710 nm.

5. The optical disc of claim 1, wherein, when a transmittance of the optical disc is measured in a wavelength range of 300 nm to 1,200 nm using a spectrophotometer, optical transmittance is 85% or more at a wavelength of 430 nm to 560 nm.

6. An optical filter comprising:
the optical disc of claim 1; and
a selective wavelength reflection layer formed on one surface or each of both surfaces of the optical disc.

7. The optical filter of claim 6, wherein the selective wavelength reflection layer has a structure formed as a dielectric multi-layered film.

8. The optical filter of claim 6, wherein, when a transmittance of the optical filter is measured in a wavelength range of 300 nm to 1,200 nm using a spectrophotometer, a shortest wavelength (λ_cut-off), in which the transmittance is 50% at a wavelength longer than a wavelength of 550 nm, is present within a wavelength of 585 nm to 615 nm.

9. The optical filter of claim 6, wherein Condition 2 below is satisfied:
10 nm<|T_{10%}−T_{50%}|<50 nm, [Condition 2]
wherein T_{50%} refers to a wavelength value at a point at which optical transmittance is 50% at a wavelength of 550 nm to 710 nm, and
T_{10%} refers to a wavelength value at a point at which optical transmittance is 10% at a wavelength of 550 nm to 710 nm.

10. The optical filter of claim 6, wherein, when a transmittance of the optical filter is measured in a wavelength range of 300 nm to 1,200 nm using a spectrophotometer, optical transmittance is 5% or less at a wavelength of 650 nm to 1,200 nm.

11. The optical filter of claim 6, wherein, when a transmittance of the optical filter is measured in a wavelength range of 300 nm to 1,200 nm using a spectrophotometer, optical transmittance is 90% or more at a wavelength of 430 nm to 560 nm.

12. A fingerprint recognition module comprising the optical filter of claim 6.

13. An organic light-emitting diode (OLED) display comprising:
an OLED display panel; and
the fingerprint recognition module of claim 12 positioned below the OLED display panel.

14. A liquid crystal display (LCD) comprising:
an LCD panel;
a backlight unit; and
the fingerprint recognition module of claim 12 positioned below the LCD panel,
wherein the fingerprint recognition module is positioned at a portion to which the backlight unit is not applied.
